(19) United States
(12) Patent Application Publication
(10) Pub. No.: US 2026/0282887 A1
(43) Pub. Date: Sep. 17, 2026

(54) SEMICONDUCTOR DEVICE HAVING GRAPHENE INTERCONNECT

(71) Applicant: Tokyo Electron Limited, Tokyo (JP)

(72) Inventor: Kandabara Tapily, Albany, NY (US)

(21) Appl. No.: 19/079,174

(22) Filed: Mar. 13, 2025

(51) Int. Cl. H01L 23/532; H01L 21/768; H01L 23/522; H01L 23/528

(52) U.S. Cl. CPC H10W 20/4462; H10W 20/034; H10W 20/045; H10W 20/056; H10W 20/42; H10W 20/43; H10W 20/435

(57) ABSTRACT

A method for making a semiconductor device can include providing a first intermediate structure including a first dielectric layer, the first dielectric layer having a first hole formed therein, where the first hole opens to an underlying conductive structure, forming a graphene-nucleation liner on a first-hole sidewall of the first hole, and forming a multi-layer-graphene structure on the graphene-nucleation liner, where the multi-layer-graphene structure includes graphene sheets, such that each of the graphene sheets has a sheet plane aligned with the first-hole sidewall of the first hole.

### TECHNICAL FIELD

The present disclosure relates generally to methods for manufacturing semiconductor devices, and more particularly, semiconductor devices having graphene interconnects.

### BACKGROUND

An integrated circuit contains various semiconductor devices and a plurality of conducting metal paths that provide electrical power to the semiconductor devices and allow the semiconductor devices to share and exchange information. Within the integrated circuit, metal layers are stacked on top of one another using intermetal and interlayer dielectric layers (ILDs) that insulate the metal layers from each other. The manufacturing stage and device portion for such intermetal and interlayer dielectric layers, or interconnects, is typically referred to as back-end-of-the-line (BEOL).

Normally, each metal layer must form an electrical contact to at least one additional metal layer. Such electrical contact can be achieved by etching a feature (i.e., a via) in the interlayer dielectric layer that separates the metal layers, and filling the resulting via with a metal to create an interconnect. A “via” sometimes refers to any feature such as a hole, line, or other similar feature formed within a dielectric layer and filled with a metal structure that provides an electrical connection or metal interconnect through the dielectric layer to another conductive structure underlying the dielectric layer. Similarly, metal structures connecting two or more vias are sometimes referred to as “trenches” or metal lines or interconnect lines.

As device feature size continues to scale to smaller geometries and dimensions, new challenges arise. One such challenge is increased resistance for tight metal pitch and smaller diameter vias. Interconnects in BEOL are becoming one of the dominant factors determining system performance and power dissipation due higher current densities (e.g., self-heating or Joule heating issues).

As the geometries shrink, capacitance in the BEOL interconnects dominates the energy consumption of the device compared to gate capacitance and diffusion capacitance at the logic circuits. As gate lengths decrease for transistors, the wire widths for metallization of the BEOL also shrinks accordingly. As the wire widths decrease, resistivity for metal conductors increases, which creates a new set of challenges. For example, RC-delay and self-heating can increase, which can degrade electromigration reliability and thereby limit current-carrying capacity and performance for interconnect structures.

More specifically, as wire width decreases, surface scatterings effect on metal resistivity increases, and more importantly barrier layer effect on metal resistivity increases exponentially. Thus, there is a need to address such increases in resistance and heating in vias and trenches for BEOL.

### SUMMARY

In an embodiment of the present disclosure, a semiconductor device can include: a first dielectric layer having a first hole therein; a first graphene-nucleation liner on a first-hole sidewall of the first hole; and a first multi-layer-graphene structure on the first graphene-nucleation liner, where the first multi-layer-graphene structure includes graphene sheets, where each of the graphene sheets has a sheet plane aligned with the first-hole sidewall of the first hole.

In an embodiment of the present disclosure, a method for making a semiconductor device can include: providing a first intermediate structure including a first dielectric layer, the first dielectric layer having a first hole formed therein, where the first hole opens to an underlying conductive structure; forming a first graphene-nucleation liner on a first-hole sidewall of the first hole; and forming a first multi-layer-graphene structure on the first graphene-nucleation liner, where the first multi-layer-graphene structure includes graphene sheets, such that each of the graphene sheets has a sheet plane aligned with the first-hole sidewall of the first hole.

In an embodiment of the present disclosure, a method for making a semiconductor device can include: providing a first intermediate structure including a first dielectric layer, the first dielectric layer having a via hole formed therein, where the via hole opens to an underlying conductive structure; forming a first graphene-nucleation liner on a via-hole sidewall of the via hole; forming a first multi-layer-graphene structure on the first graphene-nucleation liner, where the first multi-layer-graphene structure includes graphene sheets, such that each of the graphene sheets has a sheet plane aligned with the via-hole sidewall of the via hole; forming a second dielectric layer on at least part of the first dielectric layer, where the second dielectric layer includes a trench therein, where at least part of the trench opens to the first multi-layer-graphene structure of the via hole; forming a second graphene-nucleation liner on a trench sidewall of the trench; and forming a second multi-layer-graphene structure on the second graphene-nucleation liner such that the second multi-layer-graphene structure is planarly aligned with the trench sidewall of the trench and such that the second multi-layer-graphene structure is electrically connected to the underlying conductive structure via the first multi-layer-graphene structure.

### BRIEF DESCRIPTION OF THE DRAWINGS

For a more complete understanding of the present disclosure, and advantages thereof, reference is now made to the following descriptions of example embodiments taken in conjunction with the accompanying drawings, in which:

FIGS. 1A to 1H are cross-section views illustrating intermediate structures of a semiconductor device made using a method according to an embodiment of the present disclosure;

FIG. 2A is a top planar view of a via including a multi-layer graphene structure according to an embodiment of the present disclosure;

FIG. 2B is a top planar view of a via including a multi-layer graphene structure according to an embodiment of the present disclosure;

FIG. 2C is a top planar view of a trench including a multi-layer graphene structure according to an embodiment of the present disclosure;

FIG. 3 is a cross-section view illustrating an intermediate structure of a semiconductor device made using a method according to an embodiment of the present disclosure;

FIG. 4 is a cross-section view illustrating an intermediate structure of a semiconductor device made using a method according to an embodiment of the present disclosure;

FIG. 5 is a simplified diagram illustrating conductive interconnects incorporating multi-layer graphene structures according to an embodiment of the present disclosure;

FIGS. 6A to 6C are cross-section views illustrating intermediate structures of a semiconductor device made using a dual damascene method according to an embodiment of the present disclosure;

FIG. 7 is a perspective view of the graphene-nucleation liner of FIG. 6B, according to an embodiment of the present disclosure;

FIG. 8 is a flow chart of a method of making a semiconductor device in accordance with an embodiment of the present disclosure;

FIG. 9 is a flow chart of a method of making a semiconductor device in accordance with an embodiment of the present disclosure;

FIG. 10 is a flow chart of a method of making a semiconductor device in accordance with an embodiment of the present disclosure; and

FIG. 11 is a flow chart of a method of making a semiconductor device in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure. A number of example embodiments of the present disclosure are described below. Other embodiments can also be understood from the entirety of the specification as well as the claims filed herein. It can be understood that various features of different embodiments can be combined.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scopes of rights according to the present disclosure.

In the present disclosure and drawings, labels such as “M0”, “M1”, and “M2” can be used to describe various interconnect levels in the drawings, which can be commonly referred to as “metallization levels” in the semiconductor industry (even if there are conductive materials that are not metals included in the interconnect structure). However, a labeling of interconnect levels in the drawings for describing a given example embodiment of the present disclosure may not correspond to the labels used to name or identify actual interconnect levels, or to define an actual vertical location thereof, in an actual implementation of an embodiment. Thus, such labels used in the present specification do not necessarily limit an interconnect level to an actual interconnect level that implements an embodiment of the present disclosure. For example, an interconnect level labeled “M1” in present specification may correspond to an actual interconnect level located at or designated as level M5 while still being in accordance with an embodiment of the present disclosure.

Because the resistance and capacitance in the BEOL interconnects now can dominate the energy consumption of the device compared to gate capacitance and diffusion capacitance at the logic circuits, due to the continual shrinking of wire widths for metal interconnects in BEOL, there is a need for new interconnect solutions in BEOL to address these issues. Research and development into using graphene structures in BEOL has provide some solutions for these issues.

Graphene is a flat mono-layer of carbon atoms tightly packed into a two dimensional (2D) planar honeycomb lattice. Multi-layer graphene (MLG) structures can become graphite and can have a lower conductivity per layer due to inter-sheet electron hopping.

The conductivity of a bulk MLG structure can be significantly modulated by doping to greatly reduce resistivity and RC-delay to levels that can be significantly lower (e.g., more than 50% lower) than typically preferred metals for BEOL, such as copper, cobalt, tungsten, and ruthenium, for example. Doped multi-layer graphene (DMLG) (e.g., P-type intercalant doping) can have 100-fold higher current-carrying capacity compared to some metals, due to high carrier mobility and high carbon abundance. For simplification, “MLG” is used generally in the present disclosure and can include a doped (e.g., DMLG) or undoped MLG interpretation/implementation. The present disclosure presents results of research and development of MLG structures as alternatives to metals and/or to supplement metals for interconnect conductors.

Recent research and development have developed process flows using graphene as cap layers to provide low-resistance contacts between different levels of metal interconnects (e.g., where one metal layer meets and contacts another metal layer to overcome surface contact resistance issues). However, due to the planar structure of a graphene layer, the resistance of a graphene layer tends to be anisotropic. That is, the resistance of a graphene layer in directions along the sheet plane of the graphene sheet/layer can be much lower than the resistance normal to the sheet plane of the graphene sheet/layer, especially for a stack of graphene sheets/layers. Accordingly, and in accordance with an embodiment of the present disclosure, the orientation(s) of graphene sheets/layers can be structured to minimize or reduce the resistance through an MLG structure by aligning or substantially aligning the sheet planes of graphene sheets/layers with the expected axis of electrical currents in vias and trenches for a BEOL structure.

In some embodiments of the present disclosure, a method for forming a semiconductor device can include: providing a first intermediate structure including a first dielectric layer, the first dielectric layer having a hole formed therein, where the hole opens to an underlying conductive structure; forming a graphene-nucleation liner on sidewalls of the hole; and forming a multi-layer-graphene (MLG) structure on the graphene-nucleation liner, where the MLG structure includes graphene sheets, and such that all of, most of, or at least some of the graphene sheets of the MLG structure have a sheet plane aligned with the sidewalls of the hole (e.g., vertically oriented for a via hole). The hole can be mostly or substantially filled with the MLG structure such that the MLG structure is the dominant or main conductor for the interconnect structure in that hole for a BEOL structure. By having the sheet planes of the graphene sheets of the MLG structure oriented in the same direction (or along a same axis) as the current flow path for the interconnect, the conductance through the interconnect can be optimized to make use of the advantageous current capacity of graphene in sheet-plane directions.

The in-sheet-plane conductivity of an MLG structure can be increased by several tens of magnitude by intercalation doping (or exohedral doping) between graphene sheets of the MLG structure, for example. Intercalation doping can be an insertion of a dopant layer and/or dopant particles/molecules/atoms/ions between a given pair of adjacent graphene layers. The dopants can aid electrons moving between adjacent graphene sheets to reduce resistance caused by interlayer scattering. Intercalation doping can increase the carrier density due to charge transfer and can increase the mean free path due to increased layer spacing (interlayer scattering can be suppressed).

Doping can reduce the contrast between in-plane and out-of-plane conductivity for DMLG structures. DMLG can be referred to as intercalated graphite in some examples. Intercalated doping can be provided in a DMLG structure in several ways, such a in-situ flowing a precursor gas that will form the dopant along with the flow of precursor gas for forming graphene sheets, for example. It has been found that the conductivity of a DMLG structure can be enhanced with intercalation doping by exposure to dopant vapor (e.g., AsF5), for example. In some embodiments, intercalated doping can be used for making an MLG structure for an interconnect structure. In some embodiments, some, little, or no intercalated doping can be used for making a multi-graphene sheet structure (e.g., for some, a few, or all of graphene sheets of an MLG structure) for an interconnect structure. In some embodiments, the dopant for an MLG structure can include iron, nitrogen, phosphorous, potassium, calcium, copper, or any combination thereof, for example.

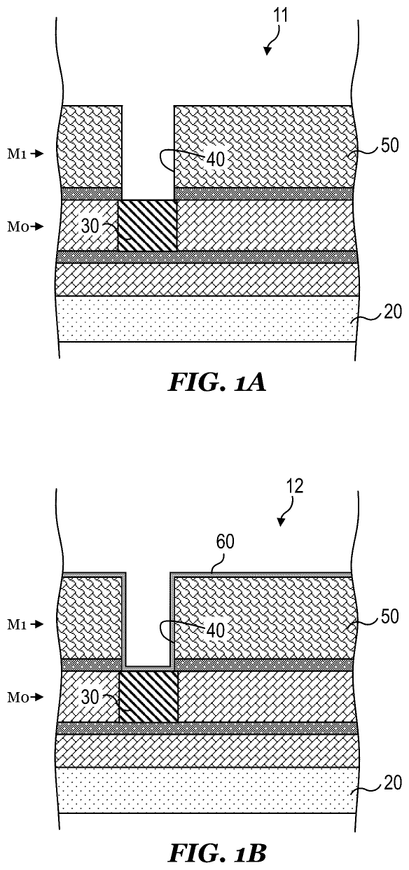

FIGS. 1A-1H, 3, 4, and 6A-6C are various cross-section views illustrating various intermediate structures during various methods of making a semiconductor device according to some example embodiments of the present disclosure. For simplification and illustration purposes, FIGS. 1A-1H, 3, 4, and 6A-6C are merely showing some portions of a semiconductor device as intermediate structures that can be relevant to a method of making the semiconductor device according to an example embodiment of the present disclosure. For example, in FIGS. 1A-1H, 3, 4, and 6A-6C, to simplify the drawings, as can be readily understood by one of ordinary skill in the pertinent art, additional layers and structures of a semiconductor device made before, under, below, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), frontend-of-line (FEOL) stages or levels, transistors, diodes, capacitors, resistors, inductors, integrated circuits, memory cells, logic, processor portions, digital devices, analog devices, semiconductor wafer, silicon-on-insulator wafer, or combinations thereof, for example. Also in FIGS. 1A-1H, 3, 4, and 6A-6C, to simplify the drawings, as can be readily understood by one of ordinary skill in the pertinent art, additional layers and structures of a substrate for a semiconductor device made after, over, above, or adjacent to the intermediate structures shown in the drawings are omitted, which can include any structures, types, and circuits of semiconductor devices, such as additional interconnects, additional vias, additional trenches, additional interlayer dielectric layers, additional intermetal dielectric layers, additional backend-of-line (BEOL) stage(s) or level(s), passivation layers, contact pads, local interconnects, global interconnects, wire bonding, packaging, or combinations thereof, for example.

In an actual completed semiconductor device cross-section, the intermediate structures, which are illustrated and represented in the drawings of the present disclosure in a simplified manner as having squared edges and/or linear shapes, can be actually more rounded, have rounded corners, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on the scale of atoms to 5 nanometers in size), or may be removed during processing and little or no remnants of certain layers, features, or portions in the final semiconductor device publicly sold and used.

FIGS. 1A to 1H are cross-section views illustrating intermediate structures of a semiconductor device, having interconnect levels M0 and M1, made using a method according to an embodiment of the present disclosure, including the use of a multi-layer-graphene (MLG) structure. Referring to FIG. 1A, a first intermediate structure 11 can include multiple levels/layers of insulating layers on a substrate 20. In the present disclosure, substrate 20 can be a very generic and simplified representation of any semiconductor structures that can be below the BEOL structure, such as a wafer, transistors, logic devices, power devices, digital circuits, analog circuits, or any combination thereof, for example, or any suitable/feasible structure, as can be apparent to one of ordinary skill in the art for which the present disclosure pertains (and thus the details of which are omitted here). Hence, the simplified representation of the substrate 20 in the drawings is not intended to be necessarily limiting.

Referring to FIG. 1A, a first intermediate structure 11 can include an M0 level including an underlying conductive structure 30. The underlying conductive structure 30 in the drawings is shown as a single block of material merely to simplify the drawings, as the underlying conductive structure 30 in some embodiments can include multiple layers of multiple materials (e.g., barrier layer, adhesion layer, metal fill, etc.) or any suitable/feasible structure, as can be apparent to one of ordinary skill in the art for which the present disclosure pertains (and thus the details of which are omitted here). Hence, the simplified representation of the underlying conductive structure 30 in the drawings is not intended to be necessarily limiting. In some embodiments, some of or most of a top surface of the underlying conductive structure 30 can be a metal material, such as copper, cobalt, or tungsten, for example.

Referring to FIG. 1A, a first dielectric layer 50 can include a via hole 40 formed therein at interconnect level M1. In some embodiments, the first dielectric layer 50 can be a single layer of one material, a single layer of a mix of multiple materials, multiple layers of one material, multiple layers of a same material or mix of multiple materials, or multiple layers of different materials, for example. In some embodiments, the material(s) of a given first dielectric layer 51 can be selected to in view of providing acceptable dielectric properties (e.g., low-k), and fitting within the process integration flow and device electrical characteristics (e.g., thermal budgets, stress inducing, non-stress inducing, thermal stress mismatching, adhesion, electrical properties, parasitic capacitance, etc.). In some embodiments, such material(s) of a given first dielectric layer 50 can include a suitable silicon dioxide (SiO₂) and structural variations thereof (e.g., flowable oxide, gel, including large air pockets, porous, etc.), for example.

In some embodiments, such material(s) of a given first dielectric layer 50 can include a low-k dielectric material, such as silicon carbonitride (SiCN), silicon oxycarbide (SiOC), silicon oxycarbonitride (SiOCN), silicon oxynitride (SiON), silicon nitride (SiN), silicon carbide (SiC), fluorinated silicon dioxide (FSG), carbon-doped oxide (CDO), organosilicate glass (OSG), silicon-carbon-oxygen-hydrogen (SiCOH), porous SiCOH, hydrogen silsesquioxane (HSQ), Methylsilsesquioxane (MSQ), nanoporous silicon dioxide, organic polymer having a third dielectric constant less than 2.6, silica-based aerogel having a fourth dielectric constant less than 2.4, spin-on organic material having a fifth dielectric constant less than 2.6, benzocyclobutene (BCB), or organosilicate material having a sixth dielectric constant less than 2.7, layers thereof, mixtures thereof, laminates thereof, or generally any combination thereof, for example.

Thus, because the first dielectric layer 50 of an embodiment can include any number or combination of layers and materials (e.g., low-k dielectric material, etch stop layer, barrier layer, etc.), or any suitable/feasible structure (as can be apparent to one of ordinary skill in the art for which the present disclosure pertains and hence the details of which are omitted here), the simplified representation of the first dielectric layer 50 in the drawings can be considered a simplified illustration and is not intended to be necessarily limiting.

In some embodiments, the first dielectric layer 50 can have a thickness in a range of 30 nm to 100 nm, while the via hole 40 can have a critical dimension (e.g., diameter) in a range of 5 nm to 20 nm, which can be a relatively high aspect ratio via hole. For example, in some embodiments, the first dielectric layer 50 can have a thickness of about 60 nm and the via hole 40 can have a diameter of about 10 nm.

Photolithography and patterning masks can be used and removed in a process flow for forming the via hole 40 of FIG. 1A, as can be apparent to one of ordinary skill in the art, and thus the details of which are omitted herein.

Referring to FIG. 1B, a graphene-nucleation layer 60 can be deposited over the first intermediate structure 11 and on sidewalls of the via hole 40, to form a second intermediate structure 12. In some embodiments, the graphene-nucleation layer 60 can be deposited so that it is conformal to the intermediate structure 11. In some embodiments, a graphene-nucleation layer 60 can be or can include material that is favorable for graphene formation (e.g., for relatively faster graphene formation). In some embodiments, a graphene-nucleation layer 60 can be or can include material that is favorable for graphene to form a well-ordered crystalline structure with large continuous lattice structures.

Research and development have shown that nickel can be used for a graphene-nucleation layer 60. For example, nickel can act as a catalyst for the formation of graphene so that the graphene can develop and form on the surface of the nickel. For example, in an embodiment, a graphene-nucleation layer 60 can be made of nickel and can have a thickness in a thickness range of 1 nm to 3 nm. In some embodiments, the graphene-nucleation layer 60 continuously covers the sidewalls of the via hole 40. In some embodiments, the graphene-nucleation layer 60 has a minimum thickness for which the graphene-nucleation layer 60 continuously covers the sidewalls of the via hole 40, such as 1 nm to 3 nm (depending upon the operation used for depositing/forming the graphene-nucleation layer 60). In some embodiments, the graphene-nucleation layer 60 can be formed using physical vapor deposition (PVD), plasma enhanced physical vapor deposition (PEPVD), chemical vapor deposition (CVD), plasma enhanced chemical vapor deposition (PECVD), atomic layer deposition (ALD), or any combination thereof, for example.

Referring to FIG. 1C, portions of the graphene-nucleation layer 60 can be removed from a top surface of the first dielectric layer 50 and a portion of the graphene-nucleation layer 60 can be removed at a bottom of the via hole 40 such that the via hole 40 opens to the underlying conductive structure 30 again, to form a graphene-nucleation liner 61 from the graphene-nucleation layer 60, and to form a third intermediate structure 13.

Because the graphene-nucleation liner 61 can be used to control where and how graphene sheets will deposit/grow/nucleate, in accordance with an embodiment of the present disclosure, some of, most of, or all of the sidewalls of the via hole 40 will be covered by or continuously covered by the graphene-nucleation liner 61. In some embodiments, part of the graphene-nucleation liner 61 may remain on the underlying conductive structure 30. In the process of removing part of the graphene-nucleation layer 60 at the bottom of the via hole 40, other parts of the graphene-nucleation layer 60 can be removed from the top surface of the first dielectric layer 50, which could be done with an anisotropic etching technique (e.g., reactive ion etching (RIE)). In some embodiments, the graphene-nucleation layer 60 can be selectively deposited only on or mostly only on the sidewalls of the via hole 40, such as using an angled PVD and/or using a SAM to shield parts of the first intermediate structure 11, for example. And in such examples, a separate step or operation of removing parts of the graphene-nucleation layer 60 to form the graphene-nucleation liner 61 (e.g., as shown in FIG. 1C) can be omitted. In some embodiments, the graphene-nucleation liner 61 can be deposited at a deposition angle relative to a wafer plane such that the graphene-nucleation liner 61 is deposited more on the sidewalls of the via hole 40 than on the underlying conductive structure 30 at a bottom of the via hole 40, for example.

FIGS. 1D to 1H illustrate stages of forming a multi-layer-graphene (MLG) structure 70 on the graphene-nucleation liner 61 in the via hole 40, in accordance with an embodiment of the present disclosure, with a goal of having all of, most of, or at least some of the graphene sheets of the MLG structure 70 having sheet planes aligned with the sidewalls of the via hole 40, such that all of, most of, or at least some of the sheet planes of the MLG structure 70 are aligned with (or oriented with) an axis or direction of a current flow path for the interconnect structure passing through the via hole 40 (e.g., aligned with an axis or direction of current flow during normal operation of the semiconductor device).

Referring to FIG. 1D, a first portion of the MLG structure 70 can be formed on the graphene-nucleation liner 61, to form a fourth intermediate structure 14. Prior to beginning the formation of the first portion of the MLG structure 70 (e.g., between FIGS. 1C and 1D), a cleaning, preparation, pretreatment, or combination thereof, of the surfaces of the graphene-nucleation liner 61 and the underlying conductive structure 30 may be performed (as described in more detail below herein).

The first portion of the MLG structure 70 can include a first-portion-sidewall portion 71 of graphene sheets/layers that can form on the graphene-nucleation liner 61, and which can be aligned with the sidewalls of the via hole 40 (e.g., can be generally vertically oriented in this example). The first portion of the MLG structure 70 can include a first-portion-hole-bottom portion 72 of graphene that can form on a top surface of the underlying conductive structure 30 at the bottom of the via hole 40. The first-portion-hole-bottom portion 72 can be aligned with a top surface of the underlying conductive structure 30. There can also be portions of graphene formed on a top surface of the first dielectric layer 50. A process of depositing/growing/forming the graphene sheets for the MLG structure 70 can be tuned so that the graphene forms more on and/or faster on the graphene-nucleation liner 61 (e.g., nickel) than other surfaces.

The graphene-nucleation liner 61 can include a material on which graphene will nucleate and grow faster or much faster than on another material of the underlying conductive structure 30 and on the dielectric material(s) of the first dielectric layer 50. Accordingly, the MLG structure 70 can grow/develop/deposit faster or much faster on the graphene-nucleation liner 61 than other exposed structures of the third intermediate structure 13 of FIG. 1C, which can provide a control of the growth/development/deposition of the graphene while forming the MLG structure 70. It can be desired to form the graphene only on the graphene-nucleation liner 61, but in reality, some graphene will also form on other exposed surfaces at rates and with adhesion strength dependent upon the material of such exposed surfaces.

Referring to FIG. 1E, a cleaning or etching operation can be performed to remove some portions of graphene deposited during the formation of the first portion of the MLG structure 70. The first-portion-hole-bottom portion 72 can be removed from a top surface of the underlying conductive structure 30, which can also remove part of the first-portion-sidewall portion 71 (but preferably not all of it). Part of the first-portion-sidewall portion 71 for the MLG structure 70 can remain because the first-portion-sidewall portion 71 can be thicker (more sheets/layers) than the first-portion-hole-bottom portion 72, and/or because the first-portion-sidewall portion 71 can have a more robust/larger sheet structure and/or more adhesion to the graphene-nucleation liner 61 than the first-portion-hole-bottom portion 72 relative to the underlying conductive structure 30. Also during the cleaning or etching operation, build up or residue of graphene on the first dielectric layer 50 (and/or other exposed surfaces) can be removed. This can result in a fifth intermediate structure 15 having one or more sheets/layers of graphene forming an initial MLG structure 70 on the graphene-nucleation liner 61 (i.e., on the sidewalls of the via hole 40 and aligned with the sidewalls of the via hole 40), as illustrated in FIG. 1E. The lower quality graphene (e.g., formed on the first dielectric layer 50 and/or on the underlying conductive structure 30) can be removed with a hydrogen plasma, for example. A very mild oxide chemical (e.g., CO₂) in a reactive ion etch (RIE) can be used to remove graphene from the bottom of the via hole (anisotropic etch), for example. If an oxide-type etch is used, then the surface of the underlying conductive structure 30 can be treated again to remove surface oxidation prior to another deposition operation for graphene, for example.

Referring to FIG. 1F, a second portion of the MLG structure 70 can be formed (grown/developed/deposited) on remaining portions of the first portion (e.g., first-portion-sidewall portion 71) of the MLG structure 70 of the fifth intermediate structure 15 of FIG. 1E, to form a sixth intermediate structure 16. The second portion of the MLG structure 70 can include a second-portion-sidewall portion 73 of graphene sheets/layers that can form on the first-portion-sidewall portion 71, and which can be aligned with the sidewalls of the via hole 40 (e.g., can be generally vertically oriented in this example). The second portion of the MLG structure 70 can include a second-portion-hole-bottom portion 74 of graphene that can form on a top surface of the underlying conductive structure 30 at the bottom of the via hole 40. The second-portion-hole-bottom portion 74 can be aligned with a top surface of the underlying conductive structure 30. Again, there can also be portions of graphene formed on a top surface of the first dielectric layer 50. A process of depositing/growing/forming the graphene sheets for the MLG structure 70 can be tuned so that the graphene forms more on and/or faster on the existing graphene sheets (e.g., remaining sheets of first-portion-sidewall portion 71) than other surfaces.

Referring to FIG. 1G, another cleaning or etching operation can be performed to remove some portions of graphene deposited during the formation of the second portion of the MLG structure 70, which can be a repeat of the cleaning/etching operation described above regarding FIG. 1E for example. The second-portion-hole-bottom portion 74 can be removed from a top surface of the underlying conductive structure 30, which can also remove part of the second-portion-sidewall portion 73 (but preferably not all of it). Part of the second-portion-sidewall portion 73 for the MLG structure 70 can remain because the second-portion-sidewall portion 73 can be thicker (more sheets/layers) than the second-portion-hole-bottom portion 74, and/or because the second-portion-sidewall portion 73 can have a more robust/larger sheet structure and/or more adhesion to the first-portion-sidewall portion 71 than the second-portion-hole-bottom portion 74 relative to the underlying conductive structure 30. Also during the cleaning or etching operation, build up or residue of graphene on the first dielectric layer 50 (and/or other exposed surfaces) can be removed. This can result in a seventh intermediate structure 17 having multiple sheets/layers of graphene further forming/developing/building-up the MLG structure 70 along the sidewalls of the via hole 40 and aligned with the sidewalls of the via hole 40, as illustrated in FIG. 1G.

Referring to FIG. 1H, another portion or more portions of the MLG structure 70 can be formed (grown/developed/deposited) on remaining portions of the second portion (e.g., second-portion-sidewall portion 73) of the MLG structure 70 of the seventh intermediate structure 17 of FIG. 1G, to complete a formation of the MLG structure 70 for an eighth intermediate structure 18. Any number of stages for growth/development/deposition and cleaning/etching alternating can be performed as needed until a desired/specified completion stage of the MLG structure 70 is achieved. The number of such stages can depend on a size, shape, and geometry of a given hole (e.g., via hole, trench hole, dual damascene via-trench combination hole), and/or can depend on material(s) selected for the graphene-nucleation liner 61 relative to materials of other exposed surfaces (e.g., underlying conductive structure 30, first dielectric layer 50) regarding graphene nucleation rate and/or graphene bonding strength, and/or can depend on a process or processes (and process parameters) used for the growth/development/deposition of the graphene (e.g., whether doped or undoped), and/or can depend on a process or processes (and process parameters) used for a clean/etch of unwanted graphene buildup (if any). In some embodiments, a cleaning/etching operation (or intermediate cleaning/etching operation) may not be needed or can be omitted for the forming of the MLG structure 70. In some embodiments, there can be many alternating stages of growth/development/deposition and cleaning/etching for the forming of the MLG structure 70.

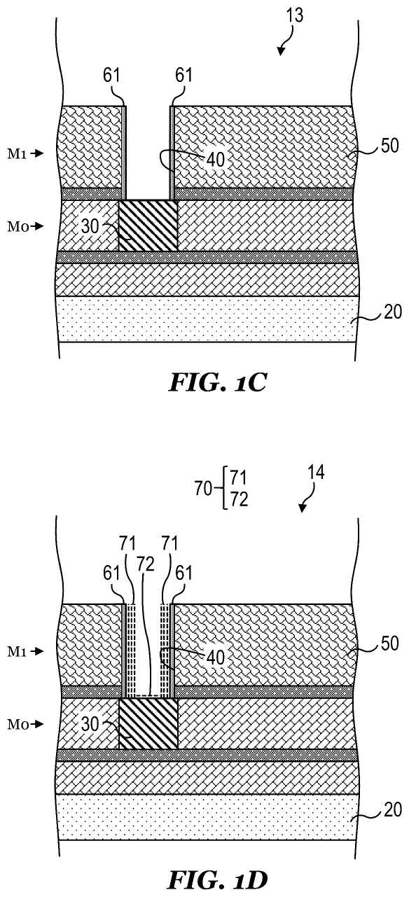

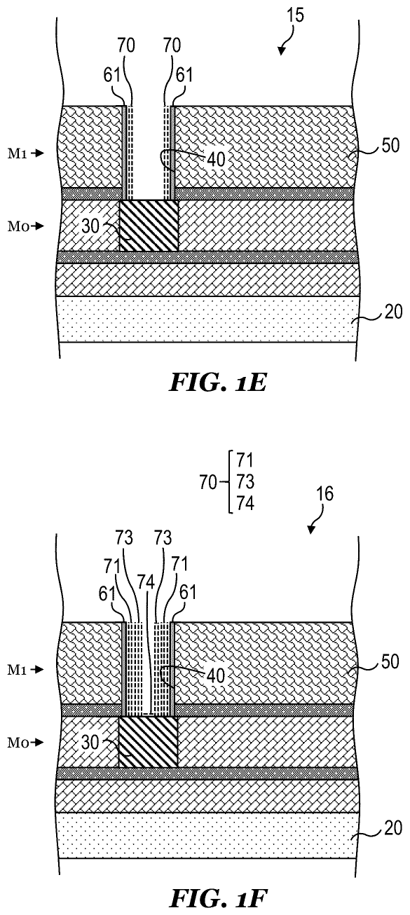

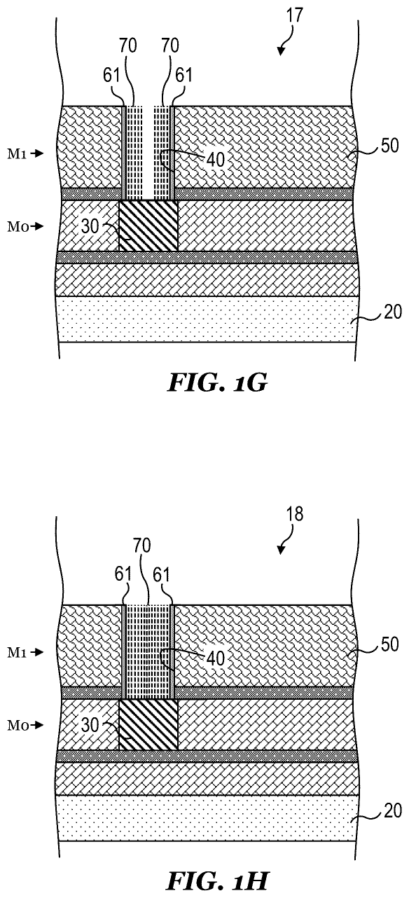

FIGS. 2A to 2C are top planar views of vias and a trench, and each includes an MLG structure according to an embodiment of the present disclosure. The via hole 40 of the eighth intermediate structure 18 of FIG. 1H can have a cylindrical shape as illustrated in FIG. 2A, for example. With a circular cross-section shape, the sidewalls of the via hole 40 can be one continuous sidewall. With a circular cross-section shape for the via hole 40, the graphene-nucleation liner 61 of FIG. 2A can have a cylindrical shape with an open bottom and an open top (or a tube shape or tubular shape), for example. Accordingly, during the formation of the MLG structure 70 (see, e.g., FIGS. 1D to 1H), the graphene sheets of the MLG structure 70 can tend to form cylindrical shapes conforming to a shape of the graphene-nucleation liner 61. The MLG structure 70 of FIG. 2A can be a set of concentric/nested/coaxial carbon nanotubes, for example. In some embodiments having a cylindrical shaped via hole, the graphene sheets of the MLG structure 70 may be generally cylindrical shaped, or partially cylindrical shaped, and a given layer or sheet may not necessarily form a continuous cylinder shape. It could be a group of overlapping partial cylindrical shapes, which could still provide a group of graphene sheets that are aligned with or substantially aligned with the sidewalls of the via hole 40 (or generally vertically oriented in this example), and which could still achieve a goal of having some of, most of, or all of the graphene sheets of an MLG structure 70 planarly aligned with an expected current path for current passing through an interconnect formed by the MLG structure through the via hole 40, for example. In some embodiments as a variation on the example embodiment illustrated in FIGS. 1H and 2A, the via hole 40 can have an oval or irregular oval or irregular circular shape for its cross-section shape. In some embodiments as a variation on the example embodiment illustrated in FIGS. 1H and 2A, the via hole 40 can have a tapered shape such that the sidewalls are not exactly vertical or such that the sidewalls are slanted, and the sidewalls can have a liner or curved shape in a height direction, for example. Thus, FIGS. 1H and 2A can be considered simplified views compared to an embodiment for an actual implementation.

The via hole 40 of the eighth intermediate structure 18 of FIG. 1H can have a square prism or rectangular prism shape as illustrated in FIG. 2B, for example. With a square or rectangular cross-section shape, the via hole 40 can have four sidewalls, for example. With a square or rectangular cross-section shape for the via hole 40, the graphene-nucleation liner 61 of FIG. 2B can have a square prism or rectangular prism shape with an open bottom and an open top (or a square/rectangular-cross-sectioned tube shape or tubular shape), for example. Accordingly, during the formation of the MLG structure 70 (see, e.g., FIGS. 1D to 1H), the graphene sheets of the MLG structure 70 can tend to form square/rectangular tubular shapes conforming to a shape of the graphene-nucleation liner 61. The MLG structure 70 of FIG. 2B can be a set of concentric/nested/coaxial carbon nanotubes, for example. In some embodiments having a square/rectangular-prism-shaped via hole, the graphene sheets of the MLG structure 70 may be generally square/rectangular prism shaped, or partially square/rectangular prism shaped, and a given layer or sheet may not necessarily form a continuous square/rectangular prism shape. It could be a group of overlapping partial square/rectangular prism shapes, which could still provide a group of graphene sheets that are aligned with or substantially aligned with the sidewalls of the via hole 40 (or generally vertically oriented in this example), and which could still achieve a goal of having some of, most of, or all of the graphene sheets of an MLG structure 70 planarly aligned with an expected current path for current passing through an interconnect formed by the MLG structure through the via hole 40, for example. In some embodiments as a variation on the example embodiment illustrated in FIGS. 1H and 2B, the via hole 40 can have a square/rectangle with rounded corners or irregular square/rectangular shape for its planar cross-section shape. In some embodiments as a variation on the example embodiment illustrated in FIGS. 1H and 2B, the via hole 40 can have a tapered shape such that the sidewalls are not exactly vertical or such that the sidewalls are slanted, and the sidewalls can have a liner or curved shape in a height direction. In some embodiments as a variation on the example embodiment illustrated in FIGS. 1H and 2B, the via hole 40 can have other planar-cross-section shapes, such as a regular/irregular pentagon, hexagon, or octagon shape, for example. Thus, FIGS. 1H and 2B can be considered simplified views compared to an embodiment for an actual implementation.

The via hole 40 of the eighth intermediate structure 18 of FIG. 1H can be a trench for forming an interconnect line extending into the page of FIG. 1H, for example, and can have a rectangular prism shape as illustrated in FIG. 2C, for example. With a rectangular cross-section shape, the via hole 40 can have four sidewalls in a shape of an interconnect trench, for example. With a rectangular cross-section shape for the via hole 40, the graphene-nucleation liner 61 of FIG. 2B can have a rectangular prism shape with an open bottom and an open top, for example. Accordingly, during the formation of the MLG structure 70 (see, e.g., FIGS. 1D to 1H), the graphene sheets of the MLG structure 70 can tend to form rectangular tubular shapes conforming to a shape of the graphene-nucleation liner 61. The MLG structure 70 of FIG. 2C can be a set of concentric/nested/coaxial carbon nanotubes, for example. In some embodiments having a rectangular-prism-shaped trench hole with a much longer length than its width, the graphene sheets of the MLG structure 70 may be only partially rectangular prism shaped, and a given layer or sheet may not necessarily form a continuous rectangular prism shape, and some graphene sheets of the MLG structure 70 may be L-shaped or single-planed flat shaped, for example. In some embodiments, the MLG structure 70 can include a group of graphene sheets of overlapping partial rectangular prism shapes, a group of L-shaped graphene sheets, a group of single-planed flat shaped graphene sheets, or some combination thereof, which could still provide a group of graphene sheets that are aligned with or substantially aligned with the sidewalls of the via hole 40 (or trench) (or generally vertically oriented in this example), and which could still achieve a goal of having some of, most of, or all of the graphene sheets of an MLG structure 70 planarly aligned with an expected current path for current passing through an interconnect formed by the MLG structure 70 through the trench, for example. In some embodiments as a variation on the example embodiment illustrated in FIGS. 1H and 2C, the via hole 40 or trench can have a rectangle with rounded corners or irregular rectangular shape for its planar cross-section shape. In some embodiments as a variation on the example embodiment illustrated in FIGS. 1H and 2C, the via hole 40 or trench can have a tapered shape such that the sidewalls are not exactly vertical or such that the sidewalls are slanted, and the sidewalls can have a liner or curved shape in a height direction. Thus, FIGS. 1H and 2C can be considered simplified views compared to an embodiment for an actual implementation.

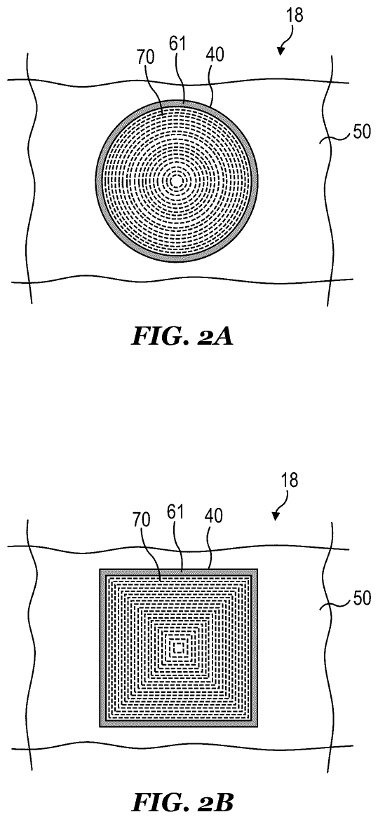

Referring to FIG. 3, a second dielectric layer 80 can be deposited over the eighth intermediate structure 18 of FIG. 1H. The second dielectric layer 80 can have a trench 82 formed therein, and at least part of the trench 82 can overlap with the via hole 40 and the MLG structure 70. A conductive interconnect structure 90 can be formed in the trench 82. At least part of the conductive interconnect structure 90 can be formed on the MLG structure 70. The conductive interconnect structure 90 can be electrically connected to the underlying conductive structure 30 via the MLG structure 70. The conductive interconnect structure 90 can be a conventional interconnect including copper, for example. The conductive interconnect structure 90 can include copper, aluminum, nickel, cobalt, ruthenium, niobium, molybdenum, tungsten, tantalum nitride, and titanium nitride, or any combination thereof, for example. A barrier layer, liner, cap layer, metal, or any combination thereof, of the conductive interconnect structure 90 can be formed directly on a top of the MLG structure 70 to provide electrical contact, for example.

The conductive interconnect structure 90 in the drawing of FIG. 3 is shown as a single block of material merely to simplify the drawings, as the conductive interconnect structure 90 in some embodiments can include multiple layers of multiple materials (e.g., barrier layer, adhesion layer, metal fill, etc.) or any suitable/feasible structure, as can be apparent to one of ordinary skill in the art for which the present disclosure pertains (and thus the details of which are omitted here). Hence, the simplified representation of the conductive interconnect structure 90 in the drawing of FIG. 3 is not intended to be necessarily limiting.

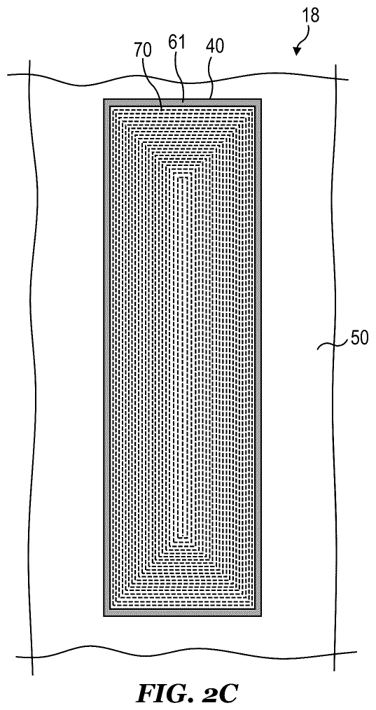

Referring to FIG. 4, the conductive interconnect structure 90 of FIG. 3 can be another MLG structure similar to and/or made in a same way as the MLG structure 70 (as described above for example). For example, the trench 82 can have a second graphene-nucleation liner 92 formed on trench sidewalls of the trench 82. A second multi-layer-graphene (MLG) structure 94 can be formed on the second graphene-nucleation liner 92. The second multi-layer-graphene structure 94 can be planarly aligned with the trench sidewalls of the trench 82. A top planar view of the second MLG structure 94 of FIG. 4 can be the same as the MLG structure 70 shown in FIG. 2C (e.g., rotated 90 degrees), for example.

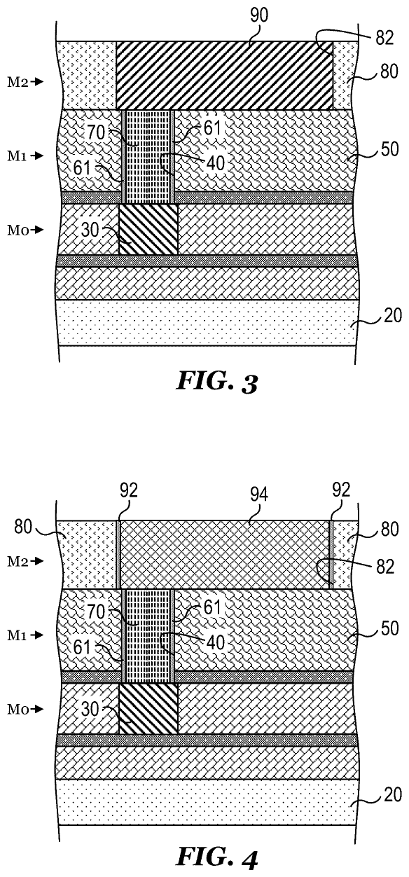

FIG. 5 is a simplified diagram illustrating conductive interconnects incorporating multi-layer graphene structures according to an embodiment of the present disclosure. FIG. 5 illustrates that multiple MLG structures for multiple conductive interconnects can be used in an embodiment of the present disclosure. FIG. 5 illustrates how each MLG structure for each of the conductive interconnects incorporating the MLG structure can have some of, most of, or all of their graphene sheets aligned with axes or directions of a current flow path. In FIG. 5, axes or directions of a current flow path are illustrated with arrows 101, 102, 103, 104. More specifically, referring to FIG. 5, a first part of the current flow path (arrow 101) goes vertically upward from an underlying conductive structure 30 through a first MLG structure 70 (e.g., through a via) to a second MLG structure 94 (e.g., a conductive line in a trench). Accordingly, some of, most of, or all of the graphene sheets of the first MLG structure 70 of FIG. 5 can be vertically oriented to be planarly aligned with the vertical axis or direction (arrow 101) of the current flow path through the first MLG structure 70.

Still referring to FIG. 5, a second part of the current flow path (arrow 102) goes horizontally to the right from the first MLG structure 70 through the second MLG structure 94 toward a third MLG structure 98 (e.g., another conductive line in another trench extending into the page of the drawing). Accordingly, some of, most of, or all of the graphene sheets of the second MLG structure 94 of FIG. 5 can be vertically oriented and extending horizontally along a trench to be planarly aligned with the horizontal axis or direction (arrow 102) of the current flow path through the second MLG structure 94.

Still referring to FIG. 5, a third part of the current flow path (arrow 103) goes vertically upward within the second MLG structure 94 toward the third MLG structure 98. Accordingly, some of, most of, or all of the graphene sheets of the second MLG structure 94 of FIG. 5 can be vertically oriented to be planarly aligned with the vertical axis or direction (arrow 103) (and/or can be a diagonal axis or direction) of the current flow path through the second MLG structure 94 toward the third MLG structure 98.

Still referring to FIG. 5, a fourth part of the current flow path (arrow 104) goes horizontally (into the page of the drawing) within the third MLG structure 98. Accordingly, some of, most of, or all of the graphene sheets of the third MLG structure 98 of FIG. 5 can be vertically oriented and extending horizontally along a trench to be planarly aligned with the horizontal axis or direction (arrow 104) of the current flow path through the third MLG structure 98.

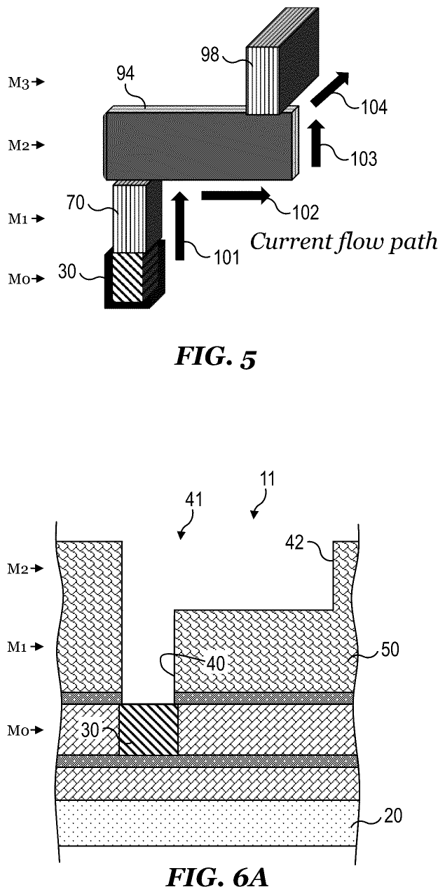

FIGS. 6A to 6C are cross-section views illustrating intermediate structures of a semiconductor device made using a dual damascene method according to an embodiment of the present disclosure. Referring to FIG. 6A, a first intermediate structure 11 can include an M0 level including an underlying conductive structure 30. A first dielectric layer 50 can include a first hole 41 formed therein using a dual damascene process flow. The first hole 41 can include a via hole 40 at interconnect level M1 and a trench 42 at interconnect level M2. The trench 42 can be contiguous with the via hole 40. First-hole sidewalls of the first hole 41 can include trench sidewalls of the trench 42 and via sidewalls of the via hole 40.

Referring to FIG. 6B, a graphene-nucleation liner 61 can be formed on the first-hole sidewalls of the first hole 41. More specifically, a graphene-nucleation liner 61 can extend continuously on at least part of the via sidewalls of the via hole 40 and on at least part of the trench sidewalls of the trench 42. The graphene-nucleation liner 61 of FIG. 6B can be formed using one of the methods described above relating to FIGS. 1B and 1C, for forming a third intermediate structure 13, for example. The bottom of the via hole 40 can be opened to the underlying conductive structure 30 (so that the underlying conductive structure 30 can be exposed at a top surface of the underlying conductive structure 30).

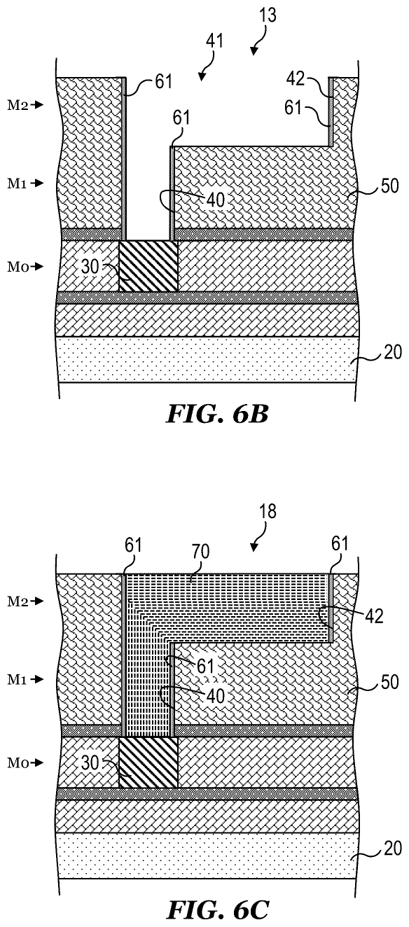

FIG. 7 is a perspective view of the graphene-nucleation liner 61 of FIG. 6B, according to an embodiment of the present disclosure. The perspective view of FIG. 7 illustrates that the graphene-nucleation liner 61 in a dual damascene embodiment can generally have an “L” shape.

Referring to FIG. 6C, an MLG structure 70 can be formed on the graphene-nucleation liner 61 in the via hole 4o and in the trench 42. The MLG structure 70 can extend continuously from the via hole 40 into the trench 42 to form a dual damascene type structure for an interconnect structure. The MLG structure 70 can provide electrical contact and a current path from the underlying conductive structure 30, through the via hole 40, into the trench 42, and along the trench 42. The MLG structure 70 of FIG. 6C can be formed using one of the methods described above relating to FIGS. 1D and 1H, for forming an eighth intermediate structure 18, for example.

The MLG structure 70 of FIG. 6C can be planarly aligned with the via sidewalls of the via hole 40 and planarly aligned with the trench sidewalls of the trench 42. A top planar view of the MLG structure 70 of FIG. 6C can be the same as the MLG structure 70 shown in FIG. 2C (e.g., rotated 90 degrees), for example. The MLG structure 70 of FIG. 6C can include graphene sheets that have portions thereof being “L” shaped and vertically oriented, for example.

In the MLG structures (70, 94, 98) of the example embodiments described above, some of, most of, or all of the graphene sheets therein can each have a sheet plane oriented at a sheet angle relative to a substrate plane of the substrate 20. Such sheet angle can be about 90 degrees (e.g., substantially vertical) in some embodiments (or for at least some graphene sheets in some embodiments), for example. Such sheet angle can be in a sheet angle range between 60 degrees and 120 degrees in some embodiments (or for at least some graphene sheets in some embodiments), for example.

Although some example embodiments of the present disclosure show and discuss a via hole filled with an MLG structure 70 for illustrating method embodiments, in other embodiments the via hole can be substituted with a trench or dual damascene (trench and via hole combination), as can be apparent to one of ordinary skill in the art. Thus, the term “via hole” used herein can be interpreted more broadly to also cover other equivalent structures (e.g., trench and/or trench-via-hole combination) making use of a method embodiment of the present disclosure.

Prior to forming an initial graphene sheet on the graphene-nucleation liner 61 and the underlying conductive structure 30 in the via hole 40 (see e.g., FIG. 1C), a cleaning treatment and/or pretreatment can be performed to remove any surface oxidation and to ensure that surfaces (especially metal surfaces) are ready to receive initial graphene sheets thereon (e.g., so that a surface of metal becomes accessible for subsequent process operations to form/deposit/grow graphene sheets thereon). In an example, an alcohol solution can be applied at room temperature for a set or selected time. The alcohol solution can include one or more alcohols or, alternatively, the alcohol solution can include one or more alcohols and a non-oxidizing solvent. The alcohol solution can contain any alcohol with a chemical formula R—OH, for example. One class of alcohols is primary alcohols, of which methanol and ethanol are the simplest members. Another class of alcohols is secondary alcohols, for example isopropyl alcohol (IPA). In certain embodiments, a wet clean with diluted hydrofluoric acid (DHF) can be performed. In certain embodiments, the optional pretreatment can also include an operation or step to remove moisture from the intermediate structure. The removal of moisture can be performed, for example, by a thermal treatment under an inert gas flow. In certain embodiments, an optional pretreatment can include a dry process using one or more reducing gases with or without a plasma.

Regarding the formation of graphene sheets for an embodiment, any suitable and/or feasible method or operation can be used to form graphene sheets (doped/intercalated and/or undoped). In some embodiments, a graphene sheet for an MLG structure 70 can be formed using a suitable deposition process (and/or a selective graphene deposition) such as a chemical vapor deposition (CVD), plasma enhanced CVD (PECVD), atomic layer deposition (ALD), or plasma enhanced ALD (PEALD) process, with an appropriate graphene precursor. The graphene deposition process can be in a non-oxide gas environment for the chamber to prevent oxidation of the graphene-nucleation liner 61 (e.g., nickel) and the underlying conductive structure 30 (e.g., cobalt, copper).

In some embodiments, a graphene sheet for an MLG structure 70 can be formed by chemical vapor deposition (CVD) for growing graphene. A gaseous precursor containing carbon can be introduced into a high-temperature reactor or chamber along with the wafer. The carbon atoms from the precursor can then react on the surface of a metal, for example, to thereby form an initial sheet of graphene. A CVD process can be continued to build up, grow, or deposit additional sheets of graphene to increase a thickness of the resulting graphene layer(s)/structure(s). The temperature and gas composition can be used to control a quality and thickness of the graphene. In some embodiments, PECVD can be used as a variation of CVD to enhance the deposition process. Plasma can provide additional energy to facilitate the growth of high-quality graphene sheets.

In some embodiments, a graphene sheet for an MLG structure 70 can be formed by liquid phase exfoliation, which can include breaking down graphite into individual graphene sheets using a solvent and then dispersing the graphene over the intermediate structure. Liquid phase exfoliation can be a scalable and relatively low-cost method of depositing graphene, but the results can be less controllable for layer uniformity compared to CVD.

In some embodiments, graphene can be epitaxially grown onto a surface having a similar crystal structure, but this process also can require high temperature and specific material properties for the metals onto which the graphene is grown.

In some embodiments, the formation of the graphene can be performed using a vapor deposition process at a temperature in a range of 40° C. to 150° C. The graphene can have a decomposition temperature range of 200° C. to 350° C.

The choice of process(es) for forming graphene sheets for an MLG structure 70 can depend on factors such as a desired graphene quality, scalability, and specific requirements of a given semiconductor application. Each process of forming graphene has its advantages and challenges, and researchers are continually exploring new techniques to improve the deposition processes for graphene.

In various embodiments, a single graphene sheet or several graphene sheets can have a thickness of one to several atomic layers (e.g., less than 1 nm). A group of graphene sheets can form a thicker graphene layer with a thickness in a range of 5 nm to 10 nm, for example. Thus, in various embodiments, an MLG structure 70 can have a total thickness up to 20 nm, for example.

In some embodiments, prior to subsequent deposition steps after forming a graphene layer, an optional post-graphene treatment, such as annealing, can be performed to remove impurities and/or improve a quality and structure of the deposited/grown graphene.

In some embodiments, the MLG structure 70 can complete the filling of the via hole 40 (and/or trench 42) to provide a completed interconnect structure. Accordingly in some embodiments, the MLG structure 70 can completely fill of the via hole 40 (and/or trench 42). In some embodiments, the MLG structure 70 can partially fill the via hole 40 (and/or trench 42). For example, in some embodiments, the MLG structure 70 can have a hollow core (e.g., in the center of the MLG structure 70), but in such case the MLG structure 70 can still act as or be the main conductive structure of a given interconnect structure. For example, if there are difference in pattern density among holes being used for forming interconnects using MLG structures, some of the MLG structures in larger holes can have a hollow core, but not necessarily. For example, if there are difference in pattern density among holes being used for forming interconnects using MLG structures, a deposition/etch alternating process (as described above) can be used to remove excess or unwanted graphene that may build up outside of the hole, for example. A blanket etch and/or a planarization (e.g., CMP) can be performed after all holes and interconnects for a given level are completed for forming MLG structures, to remove excess or unwanted graphene that may build up outside of the hole, for example.

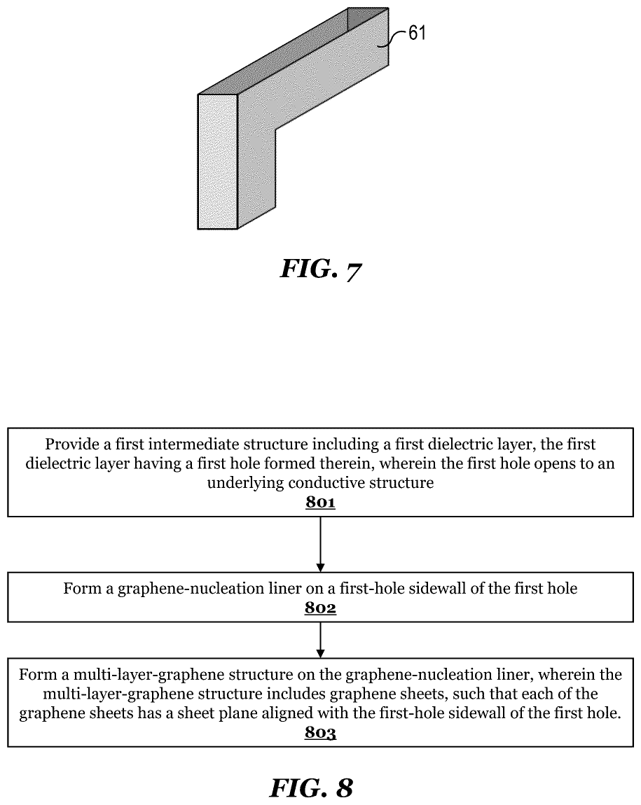

FIG. 8 illustrates a flow chart for a method of making a semiconductor device incorporating an MLG structure for an interconnect structure, in accordance with an embodiment of the present disclosure. In an embodiment, a method for making a semiconductor device includes providing a first intermediate structure including a first dielectric layer, the first dielectric layer having a first hole formed therein, where the first hole opens to an underlying conductive structure (box 801). The method includes forming a graphene-nucleation liner on a first-hole sidewall of the first hole (box 802). The method includes forming a multi-layer-graphene structure on the graphene-nucleation liner, where the multi-layer-graphene structure includes graphene sheets, such that each of the graphene sheets has a sheet plane aligned with the first-hole sidewall of the first hole (box 803).

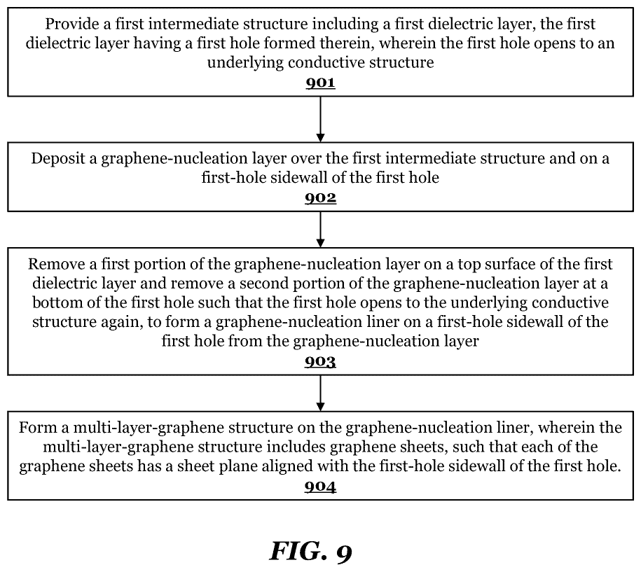

FIG. 9 illustrates a flow chart for a method of making a semiconductor device incorporating an MLG structure for an interconnect structure, in accordance with an embodiment of the present disclosure. In an embodiment, a method for making a semiconductor device includes providing a first intermediate structure including a first dielectric layer, the first dielectric layer having a first hole formed therein, where the first hole opens to an underlying conductive structure (box 901). The method includes depositing a graphene-nucleation layer over the first intermediate structure and on a first-hole sidewall of the first hole (box 902). The method includes removing a first portion of the graphene-nucleation layer on a top surface of the first dielectric layer and removing a second portion of the graphene-nucleation layer at a bottom of the first hole such that the first hole opens to the underlying conductive structure again, to form a graphene-nucleation liner on a first-hole sidewall of the first hole from the graphene-nucleation layer (box 903). The method includes forming a multi-layer-graphene structure on the graphene-nucleation liner, where the multi-layer-graphene structure includes graphene sheets, such that each of the graphene sheets has a sheet plane aligned with the first-hole sidewall of the first hole (box 904).

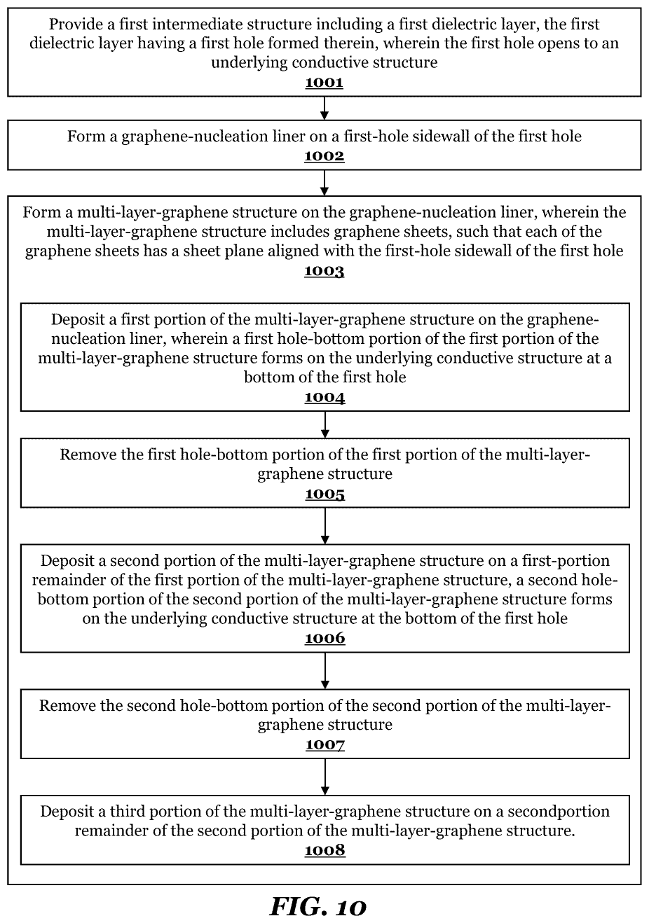

FIG. 10 illustrates a flow chart for a method of making a semiconductor device incorporating an MLG structure for an interconnect structure, in accordance with an embodiment of the present disclosure. In an embodiment, a method for making a semiconductor device includes providing a first intermediate structure including a first dielectric layer, the first dielectric layer having a first hole formed therein, where the first hole opens to an underlying conductive structure (box 1001). The method includes forming a graphene-nucleation liner on a first-hole sidewall of the first hole (box 1002). The method includes forming a multi-layer-graphene structure on the graphene-nucleation liner, where the multi-layer-graphene structure includes graphene sheets, such that each of the graphene sheets has a sheet plane aligned with the first-hole sidewall of the first hole (box 1003). The forming of the multi-layer-graphene structure includes depositing a first portion of the multi-layer-graphene structure on the graphene-nucleation liner, where a first hole-bottom portion of the first portion of the multi-layer-graphene structure forms on the underlying conductive structure at a bottom of the first hole, and where the first hole-bottom portion is aligned with a top surface of the underlying conductive structure (box 1004). The forming of the multi-layer-graphene structure includes removing the first hole-bottom portion of the first portion of the multi-layer-graphene structure (box 1005). The forming of the multi-layer-graphene structure includes depositing a second portion of the multi-layer-graphene structure on a first-portion remainder of the first portion of the multi-layer-graphene structure, where a second hole-bottom portion of the second portion of the multi-layer-graphene structure forms on the underlying conductive structure at the bottom of the first hole, and where the second hole-bottom portion is aligned with the top surface of the underlying conductive structure (box 1006). The forming of the multi-layer-graphene structure includes removing the second hole-bottom portion of the second portion of the multi-layer-graphene structure (box 1007). The forming of the multi-layer-graphene structure includes depositing a third portion of the multi-layer-graphene structure on a second portion remainder of the second portion of the multi-layer-graphene structure (box 1008).

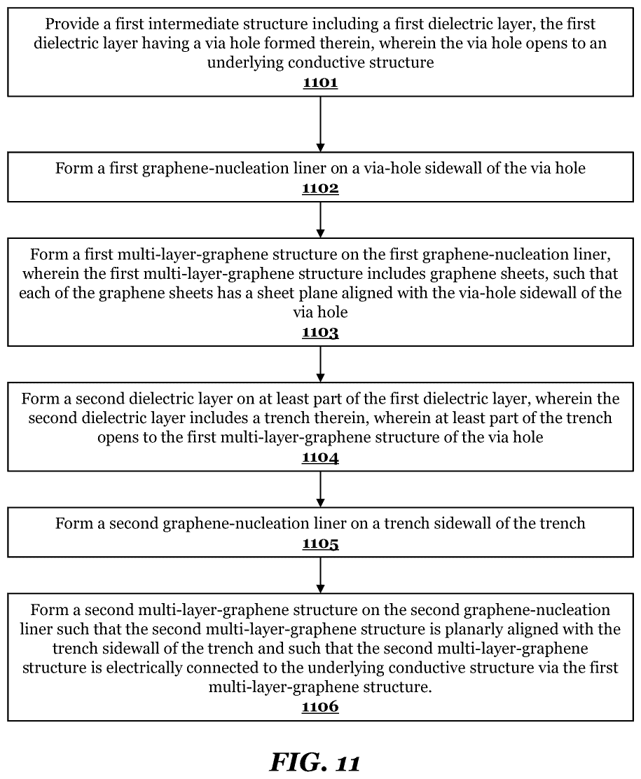

FIG. 11 illustrates a flow chart for a method of making a semiconductor device incorporating an MLG structure for an interconnect structure, in accordance with an embodiment of the present disclosure. In an embodiment, a method for making a semiconductor device includes providing a first intermediate structure including a first dielectric layer, the first dielectric layer having a via hole formed therein, where the via hole opens to an underlying conductive structure (box 1101). The method includes forming a first graphene-nucleation liner on a via-hole sidewall of the via hole (box 1102). The method includes forming a first multi-layer-graphene structure on the first graphene-nucleation liner, where the first multi-layer-graphene structure includes graphene sheets, such that each of the graphene sheets has a sheet plane aligned with the via-hole sidewall of the via hole (box 1103). The method includes forming a second dielectric layer on at least part of the first dielectric layer, where the second dielectric layer includes a trench therein, where at least part of the trench opens to the first multi-layer-graphene structure of the via hole (box 1104). The method includes forming a second graphene-nucleation liner on a trench sidewall of the trench (box 1105). The method includes forming a second multi-layer-graphene structure on the second graphene-nucleation liner such that the second multi-layer-graphene structure is planarly aligned with the trench sidewall of the trench and such that the second multi-layer-graphene structure is electrically connected to the underlying conductive structure via the first multi-layer-graphene structure (box 1106).

The method embodiments described in FIGS. 8-11 may be implemented as further described using FIGS. 1-7.

More example embodiments of the present disclosure are summarized here. Other embodiments can also be understood from the entirety of the specification as well as the claims filed herein.

Example 1. A semiconductor device including: a first dielectric layer having a first hole therein; a first graphene-nucleation liner on a first-hole sidewall of the first hole; and a first multi-layer-graphene structure on the first graphene-nucleation liner, where the first multi-layer-graphene structure includes graphene sheets, where each of the graphene sheets has a sheet plane aligned with the first-hole sidewall of the first hole.

Example 2. The semiconductor device of example 1, where the first hole includes a via hole, and where the first multi-layer-graphene structure includes dopant intercalated with at least some of the graphene sheets.

Example 3. The semiconductor device of one of examples 1 or 2, where the dopant includes at least one member from a group consisting of iron, arsenic, nitrogen, phosphorous, potassium, calcium, and copper.

Example 4. The semiconductor device of one of examples 1 to 3, where the first multi-layer-graphene structure fills at least a majority of a total volume of the first hole.

Example 5. The semiconductor device of one of examples 1 to 4, where the first graphene-nucleation liner includes a metal.

Example 6. The semiconductor device of one of examples 1 to 5, where the metal includes nickel having a thickness in a thickness range of 1 nm to 3 nm, and where the first graphene-nucleation liner continuously covers the first-hole sidewall of the first hole.

Example 7. The semiconductor device of one of examples 1 to 6, where the first graphene-nucleation liner is directly on the first-hole sidewall of the first hole, and where the first multi-layer-graphene structure is directly on the first graphene-nucleation liner.

Example 8. The semiconductor device of one of examples 1 to 7, further including a substrate configured to support the first dielectric layer, where the sheet plane is oriented at a sheet angle relative to a substrate plane of the substrate, where the sheet angle is in a sheet angle range between 60 degrees and 120 degrees.

Example 9. The semiconductor device of one of examples 1 to 8, further including an underlying conductive structure, where the first multi-layer-graphene structure is on the underlying conductive structure, where the first graphene-nucleation liner includes a first material, where the underlying conductive structure includes a second material, where the second material differs from the first material, and where graphene forms faster on the first material than the second material.

Example 10. The semiconductor device of one of examples 1 to 9, further including: a second dielectric layer on at least part of the first dielectric layer, where the second dielectric layer includes a trench therein; and a conductive interconnect structure in the trench, where at least part of the conductive interconnect structure is on the first multi-layer-graphene structure, and where the conductive interconnect structure is electrically connected to the underlying conductive structure via the first multi-layer-graphene structure.

Example 11. The semiconductor device of one of examples 1 to 10, where the conductive interconnect structure includes: a second graphene-nucleation liner on a trench sidewall of the trench; and a second multi-layer-graphene structure on the second graphene-nucleation liner, where the second multi-layer-graphene structure is planarly aligned with the trench sidewall of the trench.

Example 12. The semiconductor device of one of examples 1 to 11, where the first hole includes a trench and a via hole, where the trench is contiguous with the via hole, where the first-hole sidewall of the first hole includes a trench sidewall of the trench and a via sidewall of the via hole, where the first graphene-nucleation liner extends continuously on at least part of the via sidewall and on at least part of the trench sidewall, and where the first multi-layer-graphene structure extends continuously from the via hole into the trench.

Example 13. A method for making a semiconductor device, the method including: providing a first intermediate structure including a first dielectric layer, the first dielectric layer having a first hole formed therein, where the first hole opens to an underlying conductive structure; forming a first graphene-nucleation liner on a first-hole sidewall of the first hole; and forming a first multi-layer-graphene structure on the first graphene-nucleation liner, where the first multi-layer-graphene structure includes graphene sheets, such that each of the graphene sheets has a sheet plane aligned with the first-hole sidewall of the first hole.

Example 14. The method of example 13, where the forming of the first graphene-nucleation liner includes: depositing a first graphene-nucleation layer over the first intermediate structure and on the first-hole sidewall of the first hole; and removing a first portion of the first graphene-nucleation layer on a top surface of the first dielectric layer and removing a second portion of the first graphene-nucleation layer at a bottom of the first hole such that the first hole opens to the underlying conductive structure again, to form the first graphene-nucleation liner from the first graphene-nucleation layer.

Example 15. The method of one of examples 13 or 14, where the forming of the first multi-layer-graphene structure includes: depositing a first portion of the first multi-layer-graphene structure on the first graphene-nucleation liner, where a first hole-bottom portion of the first portion of the first multi-layer-graphene structure forms on the underlying conductive structure at a bottom of the first hole, and where the first hole-bottom portion is aligned with a top surface of the underlying conductive structure; removing the first hole-bottom portion of the first portion of the first multi-layer-graphene structure; and depositing a second portion of the first multi-layer-graphene structure on a first-portion remainder of the first portion of the first multi-layer-graphene structure.

Example 16. The method of one of examples 13 to 15, where a second hole-bottom portion of the second portion of the first multi-layer-graphene structure forms on the underlying conductive structure at the bottom of the first hole, and where the second hole-bottom portion is aligned with the top surface of the underlying conductive structure, and where the forming of the first multi-layer-graphene structure further includes: removing the second hole-bottom portion of the second portion of the first multi-layer-graphene structure; and depositing a third portion of the first multi-layer-graphene structure on a second portion remainder of the second portion of the first multi-layer-graphene structure.

Example 17. The method of one of examples 13 to 16, where the forming of the first graphene-nucleation liner includes depositing the first graphene-nucleation liner at a deposition angle relative to a wafer plane such that the first graphene-nucleation liner is deposited more on the first-hole sidewall of the first hole than on the underlying conductive structure at a bottom of the first hole.

Example 18. The method of one of examples 13 to 17, where the first hole includes a trench and a via hole, where the trench is contiguous with the via hole, where the first-hole sidewall of the first hole includes a trench sidewall of the trench and a via sidewall of the via hole, where the first graphene-nucleation liner extends continuously on at least part of the via sidewall and on at least part of the trench sidewall, and where the first multi-layer-graphene structure extends continuously from the via hole into the trench.

Example 19. The method of one of examples 13 to 18, where the first graphene-nucleation liner includes nickel having a thickness in a thickness range of 1 nm to 3 nm, where the first graphene-nucleation liner continuously covers the first-hole sidewall of the first hole, and where the first multi-layer-graphene structure includes dopant intercalated with at least some of the graphene sheets.

Example 20. A method for making a semiconductor device, the method including: providing a first intermediate structure including a first dielectric layer, the first dielectric layer having a via hole formed therein, where the via hole opens to an underlying conductive structure; forming a first graphene-nucleation liner on a via-hole sidewall of the via hole; forming a first multi-layer-graphene structure on the first graphene-nucleation liner, where the first multi-layer-graphene structure includes graphene sheets, such that each of the graphene sheets has a sheet plane aligned with the via-hole sidewall of the via hole; forming a second dielectric layer on at least part of the first dielectric layer, where the second dielectric layer includes a trench therein, where at least part of the trench opens to the first multi-layer-graphene structure of the via hole; forming a second graphene-nucleation liner on a trench sidewall of the trench; and forming a second multi-layer-graphene structure on the second graphene-nucleation liner such that the second multi-layer-graphene structure is planarly aligned with the trench sidewall of the trench and such that the second multi-layer-graphene structure is electrically connected to the underlying conductive structure via the first multi-layer-graphene structure.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A semiconductor device comprising:
a first dielectric layer having a first hole therein;
a first graphene-nucleation liner on a first-hole sidewall of the first hole; and
a first multi-layer-graphene structure on the first graphene-nucleation liner, wherein the first multi-layer-graphene structure comprises graphene sheets, wherein each of the graphene sheets has a sheet plane aligned with the first-hole sidewall of the first hole.

2. The semiconductor device of claim 1, wherein the first hole includes a via hole, and wherein the first multi-layer-graphene structure comprises dopant intercalated with at least some of the graphene sheets.

3. The semiconductor device of claim 2, wherein the dopant comprises at least one member from a group consisting of iron, arsenic, nitrogen, phosphorous, potassium, calcium, and copper.

4. The semiconductor device of claim 1, wherein the first multi-layer-graphene structure fills at least a majority of a total volume of the first hole.

5. The semiconductor device of claim 1, wherein the first graphene-nucleation liner comprises a metal.

6. The semiconductor device of claim 5, wherein the metal comprises nickel having a thickness in a thickness range of 1 nm to 3 nm, and wherein the first graphene-nucleation liner continuously covers the first-hole sidewall of the first hole.

7. The semiconductor device of claim 1, wherein the first graphene-nucleation liner is directly on the first-hole sidewall of the first hole, and wherein the first multi-layer-graphene structure is directly on the first graphene-nucleation liner.

8. The semiconductor device of claim 1, further comprising a substrate configured to support the first dielectric layer, wherein the sheet plane is oriented at a sheet angle relative to a substrate plane of the substrate, wherein the sheet angle is in a sheet angle range between 60 degrees and 120 degrees.

9. The semiconductor device of claim 1, further comprising an underlying conductive structure, wherein the first multi-layer-graphene structure is on the underlying conductive structure, wherein the first graphene-nucleation liner comprises a first material, wherein the underlying conductive structure comprises a second material, wherein the second material differs from the first material, and wherein graphene forms faster on the first material than the second material.

10. The semiconductor device of claim 9, further comprising:
a second dielectric layer on at least part of the first dielectric layer, wherein the second dielectric layer includes a trench therein; and
a conductive interconnect structure in the trench, wherein at least part of the conductive interconnect structure is on the first multi-layer-graphene structure, and wherein the conductive interconnect structure is electrically connected to the underlying conductive structure via the first multi-layer-graphene structure.

11. The semiconductor device of claim 10, wherein the conductive interconnect structure comprises:
a second graphene-nucleation liner on a trench sidewall of the trench; and
a second multi-layer-graphene structure on the second graphene-nucleation liner, wherein the second multi-layer-graphene structure is planarly aligned with the trench sidewall of the trench.

12. The semiconductor device of claim 1, wherein the first hole includes a trench and a via hole,
wherein the trench is contiguous with the via hole,
wherein the first-hole sidewall of the first hole comprises a trench sidewall of the trench and a via sidewall of the via hole,
wherein the first graphene-nucleation liner extends continuously on at least part of the via sidewall and on at least part of the trench sidewall, and
wherein the first multi-layer-graphene structure extends continuously from the via hole into the trench.

13. A method for making a semiconductor device, the method comprising:
providing a first intermediate structure comprising a first dielectric layer, the first dielectric layer having a first hole formed therein, wherein the first hole opens to an underlying conductive structure;
forming a first graphene-nucleation liner on a first-hole sidewall of the first hole; and
forming a first multi-layer-graphene structure on the first graphene-nucleation liner, wherein the first multi-layer-graphene structure comprises graphene sheets, such that each of the graphene sheets has a sheet plane aligned with the first-hole sidewall of the first hole.

14. The method of claim 13, wherein the forming of the first graphene-nucleation liner comprises:
depositing a first graphene-nucleation layer over the first intermediate structure and on the first-hole sidewall of the first hole; and
removing a first portion of the first graphene-nucleation layer on a top surface of the first dielectric layer and removing a second portion of the first graphene-nucleation layer at a bottom of the first hole such that the first hole opens to the underlying conductive structure again, to form the first graphene-nucleation liner from the first graphene-nucleation layer.

15. The method of claim 13, wherein the forming of the first multi-layer-graphene structure comprises:
depositing a first portion of the first multi-layer-graphene structure on the first graphene-nucleation liner, wherein a first hole-bottom portion of the first portion of the first multi-layer-graphene structure forms on the underlying conductive structure at a bottom of the first hole, and wherein the first hole-bottom portion is aligned with a top surface of the underlying conductive structure;
removing the first hole-bottom portion of the first portion of the first multi-layer-graphene structure; and
depositing a second portion of the first multi-layer-graphene structure on a first-portion remainder of the first portion of the first multi-layer-graphene structure.

16. The method of claim 15, wherein a second hole-bottom portion of the second portion of the first multi-layer-graphene structure forms on the underlying conductive structure at the bottom of the first hole, and wherein the second hole-bottom portion is aligned with the top surface of the underlying conductive structure, and
wherein the forming of the first multi-layer-graphene structure further comprises:
removing the second hole-bottom portion of the second portion of the first multi-layer-graphene structure; and
depositing a third portion of the first multi-layer-graphene structure on a second-portion remainder of the second portion of the first multi-layer-graphene structure.

17. The method of claim 13, wherein the forming of the first graphene-nucleation liner comprises depositing the first graphene-nucleation liner at a deposition angle relative to a wafer plane such that the first graphene-nucleation liner is deposited more on the first-hole sidewall of the first hole than on the underlying conductive structure at a bottom of the first hole.

18. The method of claim 13, wherein the first hole includes a trench and a via hole,
wherein the trench is contiguous with the via hole,
wherein the first-hole sidewall of the first hole comprises a trench sidewall of the trench and a via sidewall of the via hole,
wherein the first graphene-nucleation liner extends continuously on at least part of the via sidewall and on at least part of the trench sidewall, and
wherein the first multi-layer-graphene structure extends continuously from the via hole into the trench.

19. The method of claim 13, wherein the first graphene-nucleation liner comprises nickel having a thickness in a thickness range of 1 nm to 3 nm, wherein the first graphene-nucleation liner continuously covers the first-hole sidewall of the first hole, and wherein the first multi-layer-graphene structure comprises dopant intercalated with at least some of the graphene sheets.

20. A method for making a semiconductor device, the method comprising:
providing a first intermediate structure comprising a first dielectric layer, the first dielectric layer having a via hole formed therein, wherein the via hole opens to an underlying conductive structure;
forming a first graphene-nucleation liner on a via-hole sidewall of the via hole;
forming a first multi-layer-graphene structure on the first graphene-nucleation liner, wherein the first multi-layer-graphene structure comprises graphene sheets, such that each of the graphene sheets has a sheet plane aligned with the via-hole sidewall of the via hole;
forming a second dielectric layer on at least part of the first dielectric layer, wherein the second dielectric layer includes a trench therein, wherein at least part of the trench opens to the first multi-layer-graphene structure of the via hole;
forming a second graphene-nucleation liner on a trench sidewall of the trench; and
forming a second multi-layer-graphene structure on the second graphene-nucleation liner such that the second multi-layer-graphene structure is planarly aligned with the trench sidewall of the trench and such that the second multi-layer-graphene structure is electrically connected to the underlying conductive structure via the first multi-layer-graphene structure.
